(19) United States
(12) Patent Application Publication
(10) Pub. No.: US 2025/0308950 A1
(43) Pub. Date: Oct. 2, 2025

(54) WAFER PROCESSING METHOD AND SYSTEM USING HEATED FUNCTIONAL PLATE

(71) Applicant: Tokyo Electron Limited, Tokyo (JP)

(72) Inventors: Karthikeyan PILLAI, Albany, NY (US); Peter DELIA, Albany, NY (US); James GROOTEGOED, Albany, NY (US); Ronald NASMAN, Albany, NY (US); Norman JACOBSON, Albany, NY (US); Rodney ROBISON, Albany, NY (US)

(73) Assignee: Tokyo Electron Limited, Tokyo (JP)

(21) Appl. No.: 18/621,435

(22) Filed: Mar. 29, 2024

(51) Int. Cl. H01L 21/67; H01L 21/306; H01L 21/324

(52) U.S. Cl. CPC H01L 21/67115; H01L 21/30604; H01L 21/324; H01L 21/6708

(57) ABSTRACT

A wafer processing method and system are provided. The wafer processing system includes a controller that initiates a processing of a first semiconductor wafer in a processing space between two plates of the wafer processing system. The controller applies a heating plan to a multi-zone heater of one of the two plates during the processing of the first semiconductor wafer. The heating plan is based on a result of processing a second semiconductor wafer in the processing space without utilizing the multi-zone heater.

### FIELD OF THE INVENTION

This disclosure relates generally to the processing and surface preparation of semiconductor wafers, and particularly to a method and wafer processing system for etching of such wafers.

### BACKGROUND

Semiconductor fabrication involves many different steps of depositing, growing, patterning, removal, and cleaning of wafers. Various different materials are added and removed or partially removed, while other materials remain. One removal technique is wet etching, which typically involves immersing a semiconductor wafer into an etch solution or dispensing such a solution onto a wafer surface of the semiconductor wafer. The etch solution, when in contact with the semiconductor wafer, can chemically react with a target material to release it from the semiconductor wafer. The etched material can be typically dissolved in, or physically carried away by, the etch solution.

### SUMMARY

This disclosure provides a wafer processing method. The wafer processing method includes processing a first semiconductor wafer in a processing space between two plates of a wafer processing system. One of the two plates includes a multi-zone heater. The wafer processing method further includes applying a heating plan to the multi-zone heater during processing the first semiconductor wafer. The heating plan is based on a result of processing a second semiconductor wafer in the processing space without utilizing the multi-zone heater.

Aspects of the disclosure provides a wafer processing system, comprising a controller configured to initiate a processing of a first semiconductor wafer in a processing space between two plates of the wafer processing system, and apply a heating plan to a multi-zone heater of one of the two plates during processing the first semiconductor wafer, wherein the heating plan is based on a result of processing a second semiconductor wafer in the processing space without utilizing the multi-zone heater.

### BRIEF DESCRIPTION OF THE DRAWINGS

A more complete understanding of the present inventions and advantages thereof may be acquired by referring to the following description taken in conjunction with the accompanying drawings, in which like reference numbers indicate like features. It is to be noted, however, that the accompanying drawings illustrate only exemplary embodiments of the disclosed concepts and are therefore not to be considered limiting of the scope, for the disclosed concepts may admit to other equally effective embodiments.

FIG. 1 illustrates a schematic of a wafer processing system according to an embodiment of the disclosure.

FIG. 2 illustrates a flowchart outlining a semiconductor process according to an embodiment of the disclosure.

### DETAILED DESCRIPTION

Reference throughout this specification to “one embodiment” or “an embodiment” means that a particular feature, structure, material, or characteristic described in connection with the embodiment is included in at least one embodiment of the application, but do not denote that they are present in every embodiment. Thus, the appearances of the phrases “in one embodiment” or “in an embodiment” in various places throughout this specification are not necessarily referring to the same embodiment of the application. Furthermore, the particular features, structures, materials, or characteristics may be combined in any suitable manner in one or more embodiments.

In semiconductor device manufacturing, wafer processes are generally divided into batch and single wafer processing. The batch processing is a cost-effective approach in which multiple wafers can be processed at the same time. However, the single wafer processing is more prevalent when higher control levels are required. For example, for silicon nitride (SiN) etching, there has been a significant shift from the batch processing to the single wafer processing in the semiconductor industry. The single wafer processing requires a strict balance of various parameters such as temperature, water (H2O), and silicon content, and thus poses a hard challenge to keep many issues from happening, such as selectivity, low etch rate, uniformity, particles, and the like.

Aspects of the disclosure provide methods and systems to address these issues by using a heated functional plate that can minimize water evaporation and at the same time keep the solution temperature of a liquid chemical solution used in the single wafer processing.

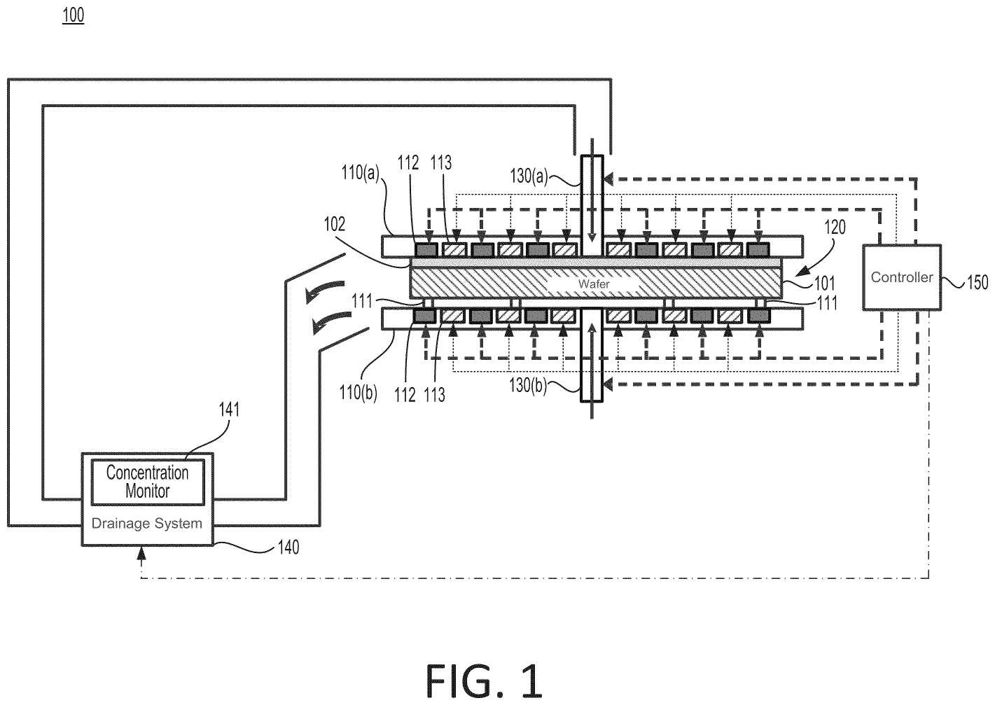

FIG. 1 illustrates a schematic of a wafer processing system 100 according to an embodiment of the disclosure. The wafer processing system 100 includes two functional plates 110(a) and 110(b). A processing space 120 can be formed between the two functional plates 110(a) and 110(b). Within the processing space 120, a semiconductor wafer 101 can be processed. Specifically, the semiconductor wafer 101 can be supported on a plurality of pins 111 that extend from the bottom plate 110(b) into the processing space 120.

The wafer processing system 100 can include chemical dispense nozzles 130(a) and 130(b). A liquid chemical solution 102 (e.g., hot phosphoric acid) can be dispensed through the chemical dispense nozzles 130(a) and/or 130(b) onto one or two surfaces of the semiconductor wafer 101. It is noted that in FIG. 1 the liquid chemical solution 102 is dispensed through the chemical dispense nozzle 130(a) onto the top surface of the semiconductor wafer 101. However, in an embodiment, the liquid chemical solution 102 can also be dispensed through the chemical dispense nozzle 130(b) onto the bottom surface of the semiconductor wafer 101.

In an embodiment, the semiconductor wafer 101 can be always stationary, and the liquid chemical solution 102 can be continuously or discontinuously dispensed during processing the semiconductor wafer 101. Specifically, the functional plates 110(a) and 110(b) physically confine the liquid chemical solution 102 within the relatively small and enclosed processing space 120, forcing the liquid chemical solution 102 to flow radially across the surfaces of the semiconductor wafer 101 without the need to rotate the semiconductor wafer 101.

According to aspects of the disclosure, the chemical dispense nozzles 130(a) and 130(b) can be disposed in or around the centers of the functional plates 110(a) and 110(b), respectively. Accordingly, the liquid chemical solution 102 can be dispensed onto the center (or around the center) of a surface of the semiconductor wafer 101, and then flow from the center to the edge of the surface of the semiconductor wafer 101. During the flowing, a concentration and/or temperature of the liquid chemical solution 102 may change because the liquid chemical solution dispensed onto the wafer surface center can react first before flowing to the wafer surface edge. The concentration and/or temperature change of the liquid chemical solution 102 can affect the performance of the liquid chemical solution 102. For example, when the liquid chemical solution 102 is an etch solution, a selectivity and/or etch rate of the etch solution may be affected due to the concentration and/or temperature change of the etch solution.

To compensate the concentration and/or temperature change, a thermal energy can be used. The thermal energy can be applied through a multi-zone heater mounted on or embedded into the functional plates 110(a) and/or 110(b). The multi-zone heater includes a plurality of heating elements 112 each for heating a respective area of the functional plates 110(a) and/or 110(b).

In an embodiment, the multi-zone heater can include one or more light sources such as a light emitting diode (LED) array or a laser array.

In an embodiment, the multi-zone heater can be implemented based on resistive heating or Peltier effect.

In an embodiment, in order to conduct the thermal energy generated by the multi-zone heater, the functional plates 110(a) and/or 110(b) can include one or more heat exchangers.

In an embodiment, the functional plates 110(a) and/or 110(b) can include a heat conducting material. In an example, the functional plates 110(a) and/or 110(b) can include a metal material coated with ethylene chlorotrifluoroethylene. In an example, the functional plates 110(a) and/or 110(b) can include at least one of an impervious synthetic graphite material, a silicon carbide material, or a ceramic material.

During processing the semiconductor wafer 101, a temperature control can be performed to monitor the temperature variation across the surfaces of the semiconductor wafer 101. For example, a temperature difference between the edge and the center of the wafer surface can be monitored by one or more temperature sensors 113 that is mounted on or embedded into the functional plates 110(a) and/or 110(b). It is noted that a number of the one or more temperature sensors 113 is not limited in this disclosure.

After processing the semiconductor wafer 101, deionized water (DIW) can be dispensed through the chemical dispense nozzles 130(a) and/or 130(b) to rinse the wafer surfaces and then isopropyl alcohol (IPA) can be dispensed.

The wafer processing system 100 can include a drainage system 140 that drains any liquid including the remaining liquid chemical solution 102 and/or the DIW and/or the IPA from the surfaces of the semiconductor wafer 101. The drainage system 140 can include a concentration monitor 141 that monitors a concentration of the drained liquid and determines whether the concentration is out of a predefined range. If the concentration of the drained liquid 102 is out of the predefined range, the drainage system 140 can adjust the concentration of the drained liquid. For example, if the concentration is above the predefined range, the DIW can be added into the drained liquid; if the concentration is below the predefined range, more liquid chemical solution 102 can be added into the drained liquid. After the drained liquid is adjusted, the adjusted liquid can be further used to process a next semiconductor wafer.

The wafer processing system 100 can further include a controller 150 that provides control signals to the functional plates 110 including the heating elements 112 and the temperature sensors 113, the chemical dispense nozzles 130, and the drainage system 140. The controller 150 can initiate a processing of the semiconductor wafer 101 in the processing space 120 between the two functional plates 110 of the wafer processing system 100. During processing the semiconductor wafer 101, the controller 150 can control the heating elements 112 of the multi-zone heater to perform a heating plan. The heating plan can be based on a result of processing a previous semiconductor wafer in the processing space 120 without utilizing the multi-zone heater.

In an embodiment, the heating plan includes an area of the at least one of the two functional plates to be heated, a temperature setting of the multi-zone heater, and/or a heating duration for the multi-zone heater.

In an embodiment, the controller 150 can control the temperature sensors 113 to perform a temperature measurement across the surfaces of the semiconductor wafer 101 and perform the temperature control based on the temperature measurement.

In an embodiment, the controller 150 can control the chemical dispense nozzles 130 to dispense the liquid chemical solution 102 onto the semiconductor wafer 101. The semiconductor wafer 101 can be processed using the liquid chemical solution 102.

In an embodiment, the controller 150 can control the drainage system 140 to drain the liquid chemical solution 102 from the processing space 120. The controller 150 can further control the concentration monitor 141 to measure the concentration of the drained liquid chemical solution, and to determine whether the concentration of the drained liquid chemical solution is out of the predefined range. If the concentration of the drained liquid chemical solution is out of the predefined range, the controller 150 can control the drainage system 140 to adjust the drained liquid chemical solution.

It is noted that the controller 150 can be implemented in a wide variety of manners. For example, any controller can be a computer and/or include one or more programmable integrated circuits that are programmed to provide the functionality described herein. One or more processors (e.g., microprocessor, microcontroller, central processing unit, etc.), programmable logic devices (e.g., complex programmable logic device (CPLD)), field programmable gate array (FPGA), etc.), and/or other programmable integrated circuits can be programmed with software or other programming instructions to implement the functionality described herein for controller. It is further noted that the software or other programming instructions can be stored in one or more non-transitory computer-readable mediums (e.g., memory storage devices, flash memory, dynamic random access memory (DRAM), reprogrammable storage devices, hard drives, floppy disks, DVDs, CD-ROMs, etc.), and the software or other programming instructions when executed by the programmable integrated circuits cause the programmable integrated circuits to perform the processes, functions, and/or capabilities described herein. Other variations could also be implemented.

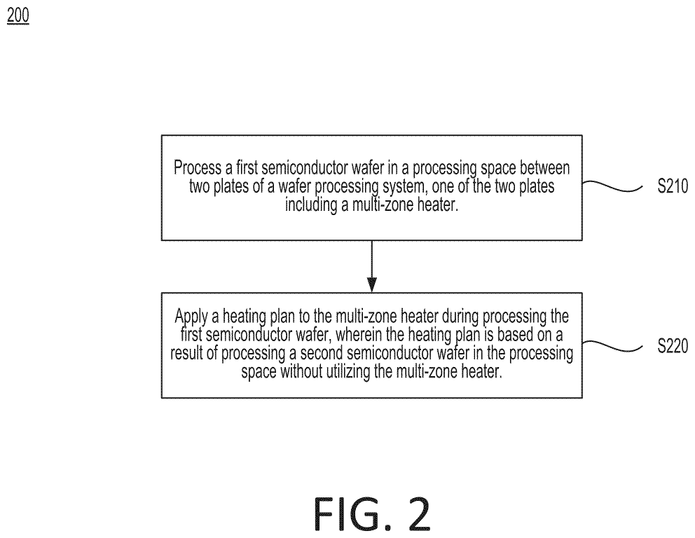

FIG. 2 illustrates a flowchart outlining a semiconductor process 200 for processing a semiconductor wafer (e.g., the semiconductor wafer 101) according to an embodiment of the disclosure. The semiconductor process 200 can be implemented by a controller (e.g., the controller 150) of a wafer processing system (e.g., the wafer processing system 100). The semiconductor process 200 can be implemented as instructions stored in a non-transitory computer-readable medium. When executed by for example the controller of the wafer processing system, the instructions can cause the wafer processing system to perform the semiconductor process 200. The semiconductor process 200 may start at step S210.

At step S210, the semiconductor process 200 can process a first semiconductor wafer (e.g., the semiconductor wafer 101) in a processing space (e.g., the processing space 120) between two plates (e.g., the functional plates 110) of a wafer processing system (e.g., the wafer processing system 100). One of the two plates includes a multi-zone heater.

At step S220, the semiconductor process 200 can apply a heating plan to the multi-zone heater during processing the first semiconductor wafer. The heating plan is based on a result of processing a second semiconductor wafer in the processing space without utilizing the multi-zone heater.

In an embodiment, the heating plan includes an area of the one of the two plates to be heated, a temperature setting, and a heating duration.

In an embodiment, the semiconductor process 200 can perform a temperature control across the first semiconductor wafer based on a temperature measurement performed by a temperature sensor (e.g., the temperature sensor 113) of the one of the two plates.

In an embodiment, the semiconductor process 200 can dispense a liquid chemical solution (e.g., the liquid chemical solution 102) onto the first semiconductor wafer. At least one surface of the first semiconductor wafer is processed using the liquid chemical solution.

In an embodiment, the semiconductor process 200 can drain the liquid chemical solution into a drainage system (e.g., the drainage system 140) of the wafer processing system. The semiconductor process 200 can measure a concentration of the drained liquid chemical solution by a concentration monitor of the drainage system, determine whether the concentration of the drained liquid chemical solution is out of a predefined range, and adjust the concentration of the drained liquid chemical solution based on the concentration of the drained liquid chemical solution being out of the predefined range.

In an embodiment, the multi-zone heater includes a light source. The light source includes a light emitting diode (LED) array or a laser array.

In an embodiment, the one of the two plates includes a heat exchanger.

In an embodiment, the one of the two plates includes a metal material coated with ethylene chlorotrifluoroethylene.

In an embodiment, the one of the two plates includes at least one of an impervious synthetic graphite material, a silicon carbide material, or a ceramic material.

Aspects of the disclosure provide a wafer processing system (e.g., the wafer processing system 100) including a controller (e.g., the controller 150) configured to initiate a processing of a first semiconductor wafer (e.g., the semiconductor wafer 101) in a processing space (e.g., the processing space 120) between two plates (e.g., the functional plates 110) of the wafer processing system, and apply a heating plan to a multi-zone heater of one of the two plates during processing the first semiconductor wafer. The heating plan is based on a result of processing a second semiconductor wafer in the processing space without utilizing the multi-zone heater.

In an embodiment, the heating plan includes an area of the one of the two plates to be heated, a temperature setting, and a heating duration.

In an embodiment, the one of the two plates includes a temperature sensor, and the controller is configured to perform a temperature control across the first semiconductor wafer during processing the first semiconductor wafer based on a temperature measurement performed by the temperature sensor.

In an embodiment, the controller is configured to control a chemical dispense nozzle (e.g., the chemical dispense nozzle 130) to dispense a liquid chemical solution (the liquid chemical solution 102) onto the first semiconductor wafer. At least one surface of the first semiconductor wafer is processed using the liquid chemical solution.

In an embodiment, the controller is configured to control a drainage system (e.g., the drainage system 140) of the wafer processing system to drain the liquid chemical solution from the first semiconductor wafer. The controller is further configured to control a concentration monitor (e.g., the concentration monitor 141) of the drainage system to measure a concentration of the drained liquid chemical solution, determine whether the concentration of the drained liquid chemical solution is out of a predefined range, and adjust the concentration of the drained liquid chemical solution based on the concentration of the drained liquid chemical solution being out of the predefined range.

In an embodiment, the multi-zone heater includes a light source. The light source includes a light emitting diode (LED) array or a laser array.

In an embodiment, the one of the two plates includes a heat exchanger.

In an embodiment, the one of the two plates includes a metal material coated with ethylene chlorotrifluoroethylene.

In an embodiment, the one of the two plates includes at least one of an impervious synthetic graphite material, a silicon carbide material, or a ceramic material.

Further modifications and alternative embodiments of the inventions will be apparent to those skilled in the art in view of this description. Accordingly, this description is to be construed as illustrative only and is for the purpose of teaching those skilled in the art the manner of carrying out the inventions. It is to be understood that the forms and method of the inventions herein shown and described are to be taken as presently preferred embodiments. Equivalent techniques may be substituted for those illustrated and described herein and certain features of the inventions may be utilized independently of the use of other features, all as would be apparent to one skilled in the art after having the benefit of this description of the inventions.

What is claimed is:

1. A wafer processing method, comprising:
processing a first semiconductor wafer in a processing space between two plates of a wafer processing system, one of the two plates including a multi-zone heater; and
applying a heating plan to the multi-zone heater during processing the first semiconductor wafer,
wherein the heating plan is based on a result of processing a second semiconductor wafer in the processing space without utilizing the multi-zone heater.

2. The wafer processing method of claim 1, wherein the heating plan includes an area of the one of the two plates to be heated, a temperature setting, and a heating duration.

3. The wafer processing method of claim 1, wherein the processing the first semiconductor wafer includes performing a temperature control across the first semiconductor wafer based on a temperature measurement performed by a temperature sensor of the one of the two plates.

4. The wafer processing method of claim 1, wherein the processing the first semiconductor wafer includes:
dispensing a liquid chemical solution onto the first semiconductor wafer,
wherein at least one surface of the first semiconductor wafer is processed using the liquid chemical solution.

5. The wafer processing method of claim 4, further comprising:
draining the liquid chemical solution into a drainage system of the wafer processing system;
measuring a concentration of the drained liquid chemical solution by a concentration monitor of the drainage system;
determining whether the concentration of the drained liquid chemical solution is out of a predefined range; and
adjusting the concentration of the drained liquid chemical solution based on the concentration of the drained liquid chemical solution being out of the predefined range.

6. The wafer processing method of claim 1, wherein the multi-zone heater includes a light source.

7. The wafer processing method of claim 6, wherein the light source includes a light emitting diode (LED) array or a laser array.

8. The wafer processing method of claim 1, wherein the one of the two plates includes a heat exchanger.

9. The wafer processing method of claim 1, wherein the one of the two plates includes a metal material coated with ethylene chlorotrifluoroethylene.

10. The wafer processing method of claim 1, wherein the one of the two plates includes at least one of an impervious synthetic graphite material, a silicon carbide material, or a ceramic material.

11. A wafer processing system, comprising:
a controller configured to
initiate a processing of a first semiconductor wafer in a processing space between two plates of the wafer processing system, and
apply a heating plan to a multi-zone heater of one of the two plates during processing the first semiconductor wafer,
wherein the heating plan is based on a result of processing a second semiconductor wafer in the processing space without utilizing the multi-zone heater.

12. The wafer processing system of claim 11, wherein the heating plan includes an area of the one of the two plates to be heated, a temperature setting, and a heating duration.

13. The wafer processing system of claim 11, wherein the one of the two plates includes a temperature sensor, and the controller is configured to perform a temperature control across the first semiconductor wafer during processing the first semiconductor wafer based on a temperature measurement performed by the temperature sensor.

14. The wafer processing system of claim 11, wherein the controller is configured to:
control a chemical dispense nozzle to dispense a liquid chemical solution onto the first semiconductor wafer,
wherein at least one surface of the first semiconductor wafer is processed using the liquid chemical solution.

15. The wafer processing system of claim 14, wherein the controller is configured to:
control a drainage system of the wafer processing system to drain the liquid chemical solution from the first semiconductor wafer;
control a concentration monitor of the drainage system to measure a concentration of the drained liquid chemical solution;
determine whether the concentration of the drained liquid chemical solution is out of a predefined range; and
adjust the concentration of the drained liquid chemical solution based on the concentration of the drained liquid chemical solution being out of the predefined range.

16. The wafer processing system of claim 11, wherein the multi-zone heater includes a light source.

17. The wafer processing system of claim 16, wherein the light source includes a light emitting diode (LED) array or a laser array.

18. The wafer processing system of claim 11, wherein the one of the two plates includes a heat exchanger.

19. The wafer processing system of claim 11, wherein the one of the two plates includes a metal material coated with ethylene chlorotrifluoroethylene.

20. The wafer processing system of claim 11, wherein the one of the two plates includes at least one of an impervious synthetic graphite material, a silicon carbide material, or a ceramic material.
